(19) United States
(12) Patent Application Publication
(10) Pub. No.: US 2020/0300409 A1
(43) Pub. Date: Sep. 24, 2020

(54) HOLDER FOR ELECTRONIC DEVICE

(71) Applicant: PARAGON AG, Belbrück (DE)

(72) Inventor: Norbert HAGENKAMP, Bad Sassendorf (DE)

(21) Appl. No.: 16/086,177

(22) PCT Filed: Apr. 19, 2016
(86) PCT No.: PCT/EP2016/000638

§ 371 Date: Oct. 13, 2018

(51) Int. Cl. F16M 13/00; H04M 1/04; H05K 5/02; B29C 39/00

(52) U.S. Cl. CPC F16M 13/00; H04M 1/04; G06F 1/1613; B29C 39/00; F16M 2200/08; H05K 5/0204

(57) ABSTRACT

A holding apparatus (1) for receiving an electronic device, for example a mobile phone, smartphone (2), tablet computer, playback device, etc., has a support surface (3) on which the electronic device (2) can be placed. In order to be able to secure electronic devices of different dimensions in the holding apparatus with comparatively little structural complexity and in order to ensure effective heat dissipation away from the electronic device, it is proposed, according to the invention, that the support surface (3) is deformable and adaptable to the outer surface (5) of different electronic devices (2) which comes into contact with the support surface (3) of the holding apparatus (1).

The invention relates to a holder for an electronic device such as a mobile phone, smart phone, tablet computer, playback device, etc. having a support surface on which the electronic device can be placed.

Such a holder is used relatively frequently in a motor vehicle, and has also become more and more common on a motorcycle.

Since both motor vehicles and motorcycles have a considerably longer service life than the above-mentioned electronic devices, and since such electronic devices have very different dimensions, considerable efforts have been made in the past to make such holders reconfigurable at a relatively low cost; for example, the actual holding parts on the holder have been designed to be interchangeable.

Proceeding from the above-described prior art, the object of the present invention is to provide a holder for electronic devices that can hold electronic devices with different dimensions without reconfiguration or the like, and that ensures improved dissipation of heat from the electronic devices, compared to the prior art.

This object is achieved according to the invention in that the support surface can deform and can adapt to the outer surface of different electronic devices, this outer surface coming into contact with the support surface of the holder. The deformability and adaptability of the support surface on the one hand ensure that electronic devices with different dimensions can be received and fixed inside the holder. In addition, the deformability and adaptability of the support surface results in an intimate contact over the entire outer surface of the electronic device opposite the support surface, regardless of whether this outer surface of the electronic device has raised or recessed sections. This counteracts the formation of air gaps between the outer surface of the electronic device and the support surface of the holder. As a result, dissipation of heat from the electronic device is improved.

According to an advantageous development of the holder according to the invention, the support surface thereof is formed by an upper side of a plastically or elastically deformable molded body. Due to the plastic or elastic deformability, the molded body adapts. When the electronic device is removed from the support surface, deformation of the molded body caused by the electronic device reverts.

If the plastically or elastically deformable molded body is a gel mat and/or a gel pad with a gel pad skin and a gel-pad filling, the gel pad skin can be optimized in terms of material in accordance with the required profile, and the gel-pad filling can be optimized according to the requirements to which it is subjected.

Alternatively, it is possible to form the support surface with the upper side of a flexible sheet, such as a film, and provide plastically or elastically deformable material, in particular plastically or elastically deformable gel, underneath the flexible sheet.

To enable wireless electrical charging of electronic devices received in the holder, it is advantageous if the holder has a charging device that can wirelessly charge the electronic device in the holder.

To improve heat dissipation of the electronic device in the holder, it is expedient if the plastically or elastically deformable material and/or the plastically or elastically deformable molded body has a high coefficient of thermal conductivity.

The charging device included in the holder can expediently be arranged in the plastically or elastically deformable molded body and/or in the gel pad. However, the charging device can also be implemented on the holder itself.

Advantageously, the holder has a rigid shell holding the flexible sheet and/or receiving the molded body or the gel pad.

Advantageously, the plastically or elastically deformable material can be between the comparatively rigid shell and the flexible sheet held in it.

In order to ensure that charging of the electronic device in the holder takes place with the highest possible degree of efficiency, it is advantageous if the molded body and/or the gel pad and/or the textile planar material of the holder has markings on the support surface for positioning the electronic device when placed on the support surface with respect to the charging device of the holder.

The holder according to the invention can be formed in such a manner that it can be used for motorcycles.

Conveniently, the holder has a cover on the shell and that can move between an open and a closed position, preferably by pivoting, and that, in its closed position, presses the electronic device against and fixes it to the plastically or elastically deformable molded body and/or the gel pad. As a result, even in the event of mechanical stresses, such as impacts, etc., the holder ensures that the electronic device remains fixed in the holder.

In order to ensure visibility and operability of the electronic device located in the holder despite the cover, it is advantageous if the part of the cover that covers the electronic device is transparent.

Embodiments of the invention will be explained in more detail below with reference to to drawings in which:

FIG. 1 is a longitudinal sectional view of an embodiment of a holder according to the invention for an electronic device;

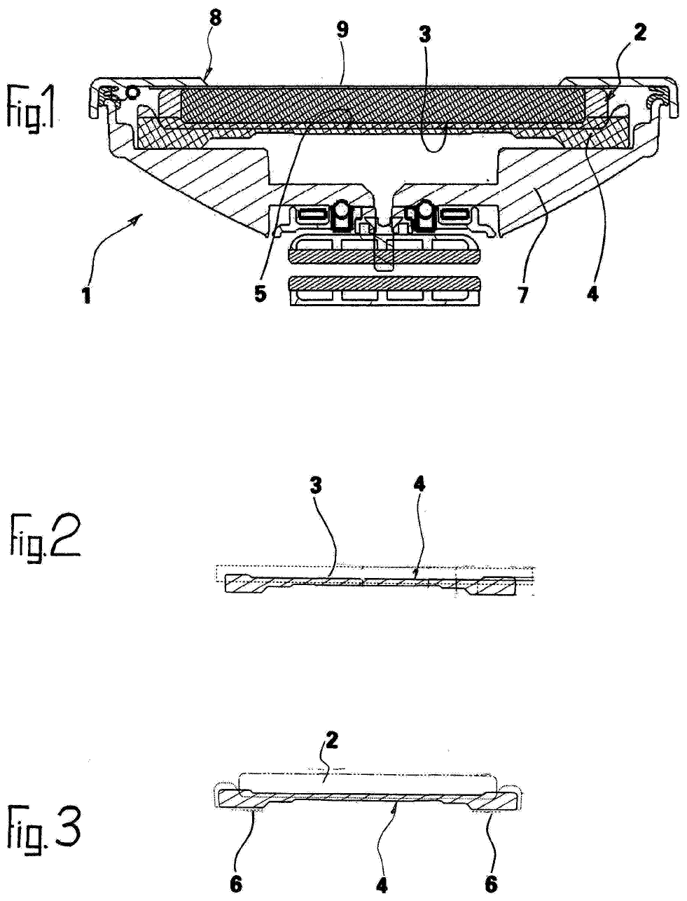

FIG. 2 shows a molded body and/or a gel pad of the embodiment of the holder according to the invention shown in FIG. 1;

FIG. 3 shows the gel pad shown in FIG. 2, on which an electronic device is placed;

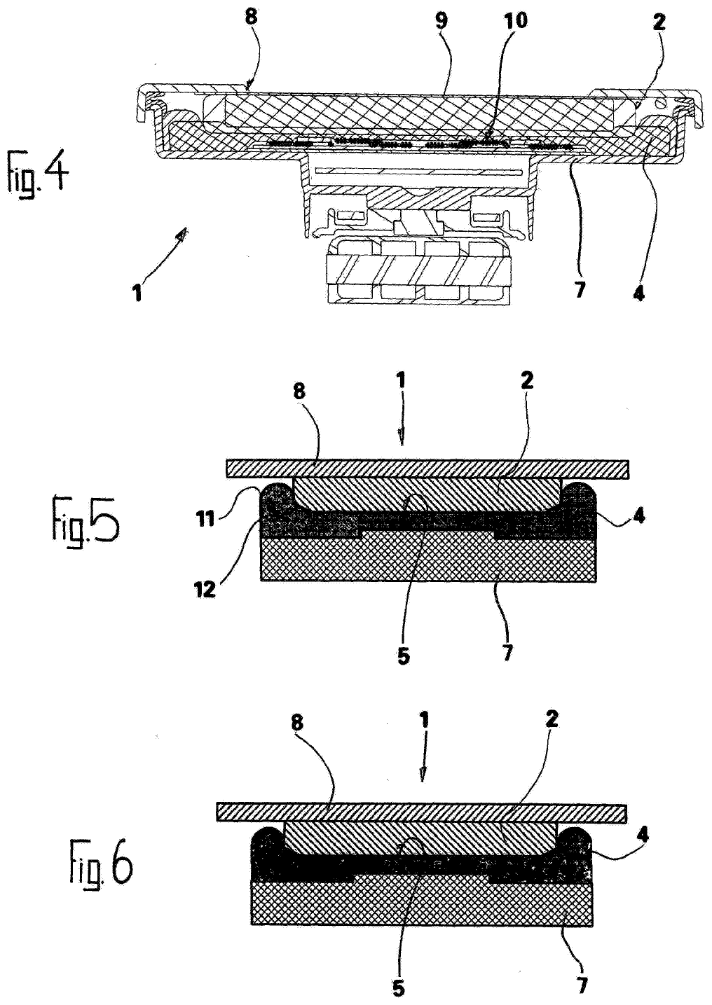

FIG. 4 shows a further embodiment of the holder according to the invention, for an electronic device;

FIG. 5 is a schematic sectional view of the holder according to the invention with a gel pad; and

FIG. 6 is a view like FIG. 5 with a molded body.

A holder 1 that is explained in more detail below with reference to FIGS. 1 to 6 usually serves for an electronic device, that is a smart phone 2 in the illustrated embodiments.

Instead of a smart phone 2, however, a different type of electronic device, such as a mobile phone, a tablet computer, a playback device, or a similar device can be received in the holder 1.

For placement of the smart phone 2, the holder 1 has a support surface 3 that is formed in the illustrated embodiments by a plastically or elastically deformable molded body 4.

Due to the plastic or elastic deformability of the molded body 4, the correspondingly also deformable support surface 3 conforms in shape to the outer surface 5 of the smart phone 2 in contact with it. Accordingly, regardless of the specific contour and/or design of the outer surface 5 of the smart phone 2 that can have, for example, a camera or other projections, indentations, etc. on the outer surface 5, surface contact is established between the outer surface 5 of the smart phone 2 and the support surface 3 of the molded body 4.

Due to the plastic or elastic deformability of the molded body 4, previous deformations of same revert as soon as the smart phone 2 is removed from the holder 1.

In FIGS. 2 and 3, the molded body 4 is shown in section. In FIG. 2, a region into which the molded body 4 can deform is indicated above and/or in the upper region of the molded body by the dotted lines.

In FIG. 3, the smart phone 2 is shown by a dot-dash line, and the molded body 4 assumes the shape indicated in FIG. 3 by the dotted line when the smart phone 2 is placed on the support surface 3.

In FIG. 3, two dashed lines indicate an adhesive surface 6 that connects the molded body 4 to a relatively rigid shell 7 of the holder 1, shown in FIG. 1.

FIG. 1 also indicates how the molded body 4 deforms when the smart phone 2 is placed on the support surface 3.

In the illustrated embodiment, the holder 1 has a cover 8 pivotally mounted on it that can be moved between an open position and the closed position shown in FIG. 1. In the closed position, the cover 8 pushes the smart phone 2 against the support surface 3 and/or the molded body 4. This ensures surface contact between the outer surface 5 of the smart phone 2 and the support surface 3 of the molded body 4.

In order to ensure the visibility and operability of the smart phone 2 even when the cover 8 is closed, the cover 8 has a transparent section 9 in its region that covers the smart phone 2.

In the embodiment shown in FIG. 4, the holder 1 is equipped with a charging device 10 that can wirelessly charge the smart phone 2 when it is in the holder 1. The molded body 4 is correspondingly formed from a material that allows wireless electrical charging of the smart phone 2 by the charging device without appreciable electrical losses.

Furthermore, the molded body 4 is made of a material that has a high coefficient of thermal conductivity such that heat can be dissipated as quickly as possible through the molded body 4 and the shell 7 of the holder 1 that receives it during the smart phone 2 charging process.

In the schematic view of FIG. 5, the molded body 4 is designed as a gel pad 4 that is formed by a gel pad skin 11 and a gel-pad filling 12. The material of the gel pad skin can then be optimized with regard to the demands made on this gel pad skin 11, which also applies to the material of the gel-pad filling 12.

In contrast, in the illustration in FIG. 6, a monolithic molded body 4 is shown.

As can be seen from both illustrations, the smart phone 2 is pressed by the cover 8 against the support surface formed by the molded body and/or gel pad 4. The support surface 3 of the molded body and/or gel pad 4 then sits flat against the given outer surface 5 of the smart phone 2. Air gaps or the like between the support surface 3 and the outer surface 5 of the smart phone 2 are prevented.

The holder 1 can be designed in such a manner that it can act as a holder that can be used on a motorcycle. In the embodiment as a holder 1 for motorcycles, the cover 8 is particularly useful, since it ensures a protected accommodation of the smart phone 2, and the transparent cover portion 9 ensures visibility of the smart phone 2.

Of course, the above-described holder 1 can also be used inside a vehicle.

1. A holder for an electronic device, the holder comprising:
a support surface on which the electronic device can be placed, the support surface being deformable and shapable to the outer surface of different electronic devices that come into contact with the support surface of the holder.

2. The holder according to claim 1, wherein the support surface is formed by an upper side of a plastically or elastically deformable molded body.

3. The holder according to claim 2, wherein the plastically or elastically deformable molded body is a gel mat or a gel pad with a gel pad skin and a gel-pad filling.

4. The holder according to claim 1, wherein the support surface is formed by an upper side of a flexible sheet or film on whose lower side is provided plastically or elastically deformable gel.

5. The holder according to claim 1, further comprising:
a charging device that can wirelessly charge the electronic device in the holder.

6. The holder according to claim 2, wherein the plastically or elastically deformable body has a high coefficient of thermal conductivity.

7. The holder according to claim 5, wherein the charging device is in the plastically or elastically deformable molded body.

8. The holder according to claim 4, further comprising:
a rigid shell in which the flexible sheet is held or the molded body or the gel pad is received.

9. The holder according to claim 8, wherein the plastically or elastically deformable material is between the rigid shell and the flexible sheet held thereon.

10. The holder according to claim 5, further comprising:
markings on the support surface for positioning the electronic device when placed on the support surface with respect to the charging device of the holder.

11. (canceled)

12. The holder according to claim 8, further comprising:
a cover on the shell and movable between an open position and a closed position, and that, in its closed position, presses the electronic device against and fixes it to the plastically or elastically deformable molded body or the gel pad.

13. The holder according to claim 12, wherein the cover is transparent in a cover section thereof that covers the electronic device.

14. The holder according to claim 1, wherein the body is made at least partially of an elastically and plastically deformable material that can deform to fit around and to a rear surface of the electronic device but that reverts to its original shape when the device is removed.
